(19) United States
(12) Patent Application Publication
(10) Pub. No.: US 2013/0027596 A1
(43) Pub. Date: Jan. 31, 2013

(54) COLOR IMAGING USING TIME-MULTIPLEXED LIGHT SOURCES AND MONOCHROME IMAGE SENSORS WITH MULTI-STORAGE-NODE PIXELS

(71) Applicant: Chung Chun Wan, Fremont, CA (US)

(72) Inventor: Chung Chun Wan, Fremont, CA (US)

(21) Appl. No.: 13/557,656

(22) Filed: Jul. 25, 2012

Related U.S. Application Data
(60) Provisional application No. 61/512,315, filed on Jul. 27, 2011.

(51) Int. Cl. H01L 27/148; H04N 9/04

(52) U.S. Cl. 348/302; 348/294; 257/225; 348/E09.01; 257/E27.15

(57) ABSTRACT

Electronic devices may include monochrome image sensors having multi-storage-node image sensor pixels. A multi-storage-node image pixel may be synchronized with artificial light sources of different colors and may include a floating diffusion region and multiple storage regions. The image pixels may be sequentially exposed to each light color and may store charge associated with each color in each of the different storage regions. After exposure, the stored charge may be transferred to the floating diffusion region and subsequently read out using readout circuitry. The image pixel may have one set of storage gates that can perform both storage and transfer functions. Alternatively, the image pixel may have a first set of transfer gates for transferring charge to the storage regions and a second set of transfer gates for transferring charge from the storage regions to the floating diffusion region.

This application claims the benefit of provisional patent application No. 61/512,315, filed Jul. 27, 2011, which is hereby incorporated by reference herein in its entirety.

### BACKGROUND

This invention relates generally to imaging devices, and more particularly, to imaging devices with monochrome image sensors that form color images using time-multiplexed light sources.

Image sensors are commonly used in electronic devices such as cellular telephones, cameras, and computers to capture images. An electronic device is provided with an image sensor that includes a large number of image sensor pixels to convert light to electric charge.

In a typical color imaging arrangement, a color filter array (CFA) arranged using the Bayer color filter pattern is placed on top of the image sensor pixels so that either red light, green light, or blue light is passed through to each pixel (i.e., each pixel can either output a red image value, a green image value, or a blue image value). Image values surrounding a given pixel are subsequently interpolated via a process sometimes referred to as demosaicking to generate missing color image values for that pixel. For example, a given pixel positioned underneath a red color filter may output a red image value that can then be combined with blue image values and green image values interpolated from neighboring pixels. Interpolating color image values in this way may result in reduced color fidelity and generation of undesired color distortions such as Moiré patterns. Also, since each color filter only transmits one color of light, much of the light that is incident on the CFA is absorbed, resulting in reduced quantum efficiency and increased image sensor pixel crosstalk.

In an effort to alleviate these problems, color imaging using a monochrome image sensor and artificial light sources has been developed. In a conventional monochrome image sensor of this type, artificial light sources including red light, green light, and blue light are emitted towards a subject. Following exposure with the red light, a first image is captured. Following exposure with the green light, a second image is captured. Following exposure with the blue light, a third image is captured. The first, second, and third captured images are then merged to form a combined color image. While eliminating the CFA increases color fidelity and quantum efficiency, any motion that occurs between each successive capture of the three color images will create severe color artifacts (i.e., the three color images may not be properly align with respect to one another in the final combined color image).

It would therefore be desirable to be able to provide improved imaging devices with monochrome image sensors.

### BRIEF DESCRIPTION OF THE DRAWINGS

FIG. 1 is a circuit diagram of a conventional image sensor pixel.

FIG. 2 is a diagram of a conventional color filter array formed over an image sensor.

FIG. 3 is a timing diagram illustrating an exposure and readout sequence associated with operating a conventional monochrome image sensor.

FIG. 4 is a timing diagram illustrating an interleaving exposure and readout sequence associated with operating a monochrome image sensor having multi-storage-node image sensor pixels in accordance with an embodiment of the present invention.

FIG. 5 is a circuit diagram of an illustrative multi-storage-node image sensor pixel with sequentially-connected transfer gates in accordance with an embodiment of the present invention.

FIG. 6 is a cross-sectional side view of the illustrative multi-storage-node image sensor pixel of FIG. 5 in accordance with an embodiment of the present invention.

FIG. 7 is a timing diagram illustrating the operation of the multi-storage-node image sensor pixel of FIGS. 5 and 6 in accordance with an embodiment of the present invention.

FIG. 8 is a circuit diagram of an illustrative multi-storage-node image sensor pixel having a storage gate with a built-in voltage barrier in accordance with an embodiment of the present invention.

FIG. 9 is a cross-sectional side view of the multi-storage-node image sensor pixel of FIG. 8 in accordance with an embodiment of the present invention.

FIG. 10 is a timing diagram illustrating the operation of the multi-storage-node image sensor pixel of FIGS. 8 and 9 in accordance with an embodiment of the present invention.

FIG. 11 is a diagram illustrating one suitable layout arrangement for the illustrative multi-storage-node image sensor pixel of the type shown in FIGS. 5, 6, 9, and 10 in accordance with an embodiment of the present invention.

FIG. 12 is a block diagram of a processor system employing the image sensor of FIGS. 4-11 in accordance with an embodiment of the present invention.

### DETAILED DESCRIPTION

Electronic devices such as digital cameras, computers, cellular telephones, medical endoscopes, and other electronic devices include image sensors that gather incoming light to capture an image. The image sensors may include large arrays of image sensor pixels (sometimes referred to as image pixels). The image pixels may include photosensitive elements such as photodiodes that convert the incoming light into image signals. Image sensors may have any number of image pixels (e.g., hundreds or thousands or more). A typical image sensor may, for example, have hundreds or millions of image pixels (e.g., megapixels). Image sensors may include control circuitry, such as circuitry for operating the image pixels, and readout circuitry for reading out image signals corresponding to the electric charge collected using the photosensitive elements.

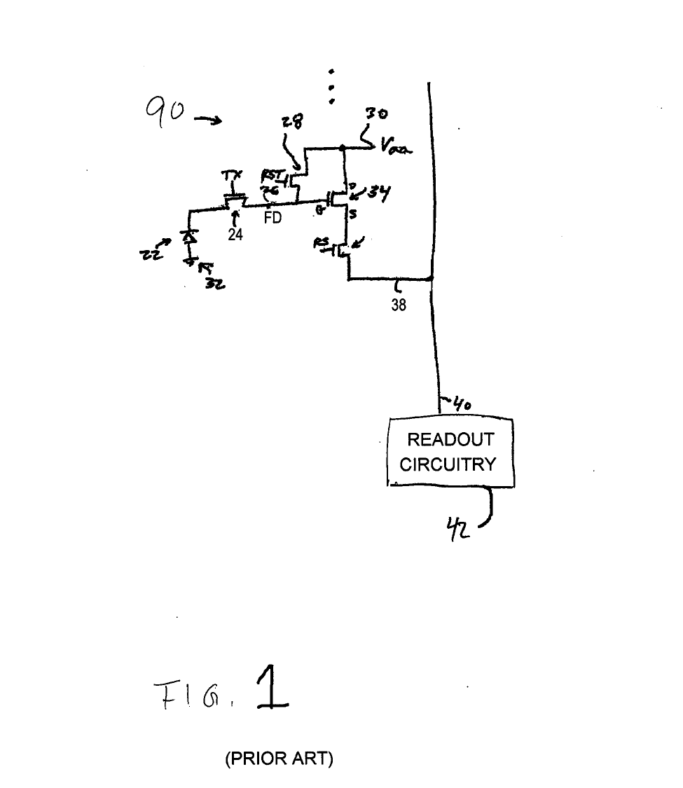

FIG. 1 is a circuit diagram of a conventional image sensor pixel 90. As shown in FIG. 1, image pixel 90 includes a photosensitive element such as photodiode 22, charge transfer transistor 24, reset transistor 28, source follower transistor 34, and row select transistor 36. A positive power supply voltage (e.g., positive power supply voltage Vaa or another reset-level voltage) is supplied at positive power supply terminal 30. A ground power supply voltage (e.g., ground power supply voltage Vss) is supplied at ground terminal 32. Incoming light is detected by a photosensitive element such as photodiode 22 after passing through a color filter structure. Photodiode 22 converts the incoming light to electrical charge.

In particular, photodiode 22 includes a p-type terminal that is connected to ground terminal 32 and an n-type terminal that is coupled to a floating diffusion (FD) node 26 via charge transfer transistor 24. Reset transistor 28 is connected between floating diffusion node 26 and power supply terminal 30. Transistor 34 has a gate G that is connected to FD node 26, a drain D that is connected to power supply terminal 30, and source S that is coupled to pixel output path 38 via row select transistor 36. Output path 38 of each pixel 90 is connected to a shared column line 40 that is connected to readout circuitry 42.

Before an image is acquired, reset control signal RST is asserted. Asserted signal RST turns on reset transistor 28 and resets floating diffusion node 26 to Vaa or another reset-level voltage. The reset control signal RST is then deasserted to turn off reset transistor 28. After the reset process is complete, transfer gate control signal TX is asserted to turn on transfer transistor 24. When transfer transistor 24 is turned on, charge that has been collected at photodiode 22 in response to incoming light is transferred to charge storage node 26. The signal associated with the stored charge on node 26 is conveyed to row select transistor 36 via source-follower transistor 34.

When it is desired to read out the value of the stored charge (i.e., the value of the stored charge that is represented by the signal at the source S of transistor 34), row select control signal RS is asserted. When signal RS is asserted, transistor 36 turns on and a corresponding signal Vout that is representative of the magnitude of the charge on floating diffusion node 26 (i.e., a reset-level or an image-level from photodiode 22) is produced on output path 38. In a typical configuration, there are numerous rows and columns of image pixels in an image sensor. When row select control signal RS is asserted in a given row, a path such as column line 40 is used to route signal Vout from that image pixel to readout circuitry. Reset-levels and image levels are sampled, held, and converted for each image pixel 90 to allow for noise compensation.

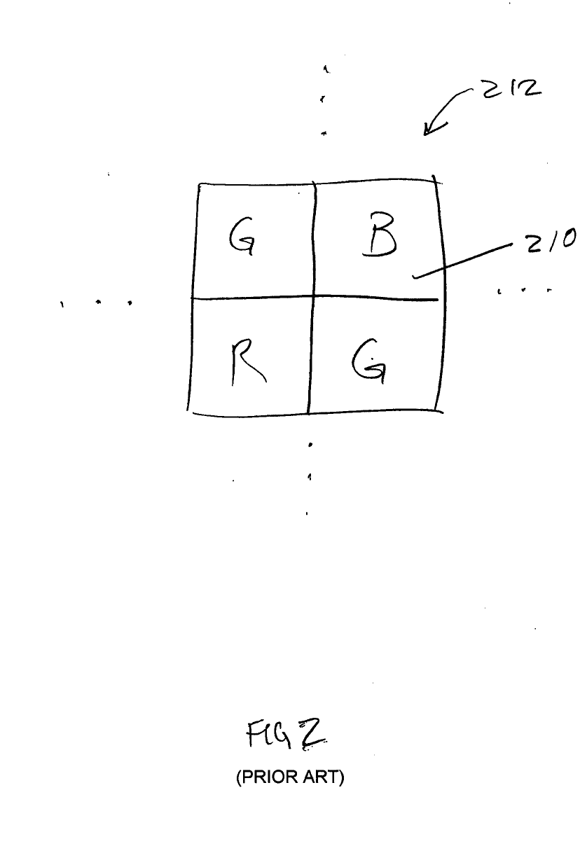

In conventional color imaging processes, an image sensor is provided with image pixels 90 formed under color filters. As shown in FIG. 2, color filters 210 are arranged in a color filter array (CFA) 212 that includes many rows and columns of color filters 210. CFAs 212 typically include color filters 210 arranged in repeating patterns such as the Bayer pattern as shown in FIG. 2. Each color filter 210 transmits either red light, green light, or blue light. One image pixel 90 is placed under each color filter 210 so that each image pixel 90 only receives light of one color. When capturing an image, each image pixel 90 creates an image signal corresponding to the light of one color but lacks information about the imaged scene corresponding to the other two colors. Software interpolation methods are used to perform de-mosaicking on the resulting images in order to provide information about the two colors not captured by each image pixel. By using de-mosaicking techniques such as interpolation, some color fidelity is lost in the final image as color values are created by software algorithms to guess the two missing color values for each pixel. Implementing CFA 212 in color imaging also results in decreased quantum efficiency and increased crosstalk in the image sensor due to light absorption by CFA 212.

Monochrome image sensors have been developed to allow for color imaging without use of a color filter array. In a conventional monochrome image sensor, three artificial light sources sequentially illuminate a scene. Immediately after illumination of the scene with red light, a first red image may be captured and read out. Immediately after illumination of the scene with green light, a second green image may be captured and read out. Immediately after illumination of the scene with blue light, a third blue image may be captured and read out. A final color image can then be formed by combining the three captured image signals.

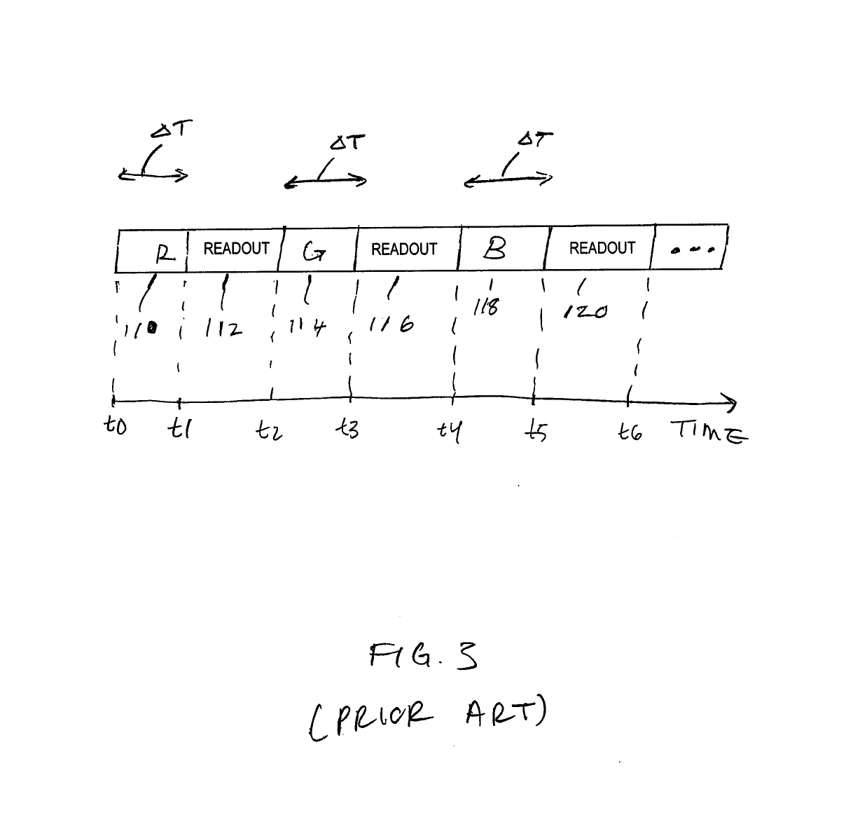

FIG. 3 shows a timing diagram for illustrating an exposure and readout sequence associated with a conventional monochrome image sensor utilizing artificial red (R), green (G), and blue (B) light sources. During red light exposure phase 110 (i.e., from time t0 to t1), red light is used to illuminate a scene. During phase 110, pixels 90 in the monochrome image sensor are used to detect red light that has been reflected back from the illuminated scene. The image signals generated during phase 110 are subsequently read out during readout phase 112 (i.e., from time t1 to t2).

During green light exposure phase 114 (i.e., from time t2 to t3), green light is used to illuminate the scene. During phase 114, pixels 90 in the monochrome image sensor are used to detect green light that has been reflected back from the illuminated scene. The image signals generated during phase 114 are subsequently read out during readout phase 116 (i.e., from time t3 to t4).

During blue light exposure phase 118 (i.e., from time t4 to t5), blue light is used to illuminate the scene to be captured. During phase 118, pixels 90 are used to detect blue light that has been reflected back from the illuminated scene. The image signals generated during phase 118 are subsequently read out during readout phase 120 (i.e., from time t5 to t6). Red light exposure phase 110, green light exposure phase 114, and blue light exposure phase 118 may have a duration ΔT. The image signals read out during readout phases 112, 116, and 120 can then be combined to form a final color image. Since phases 110, 114, and 118 are separated in time by readout phases 112 and 116, any motion that occurs in the scene between times t0 and t5 will cause the red, green, and blue images captured by the image sensor to be misaligned when they are combined. Motion blur captured using the conventional monochrome image sensor can result in unwanted color artifacts in the combined color image. It may therefore be desirable to provide imaging devices having monochrome image sensors that are capable of reducing such types of color artifacts.

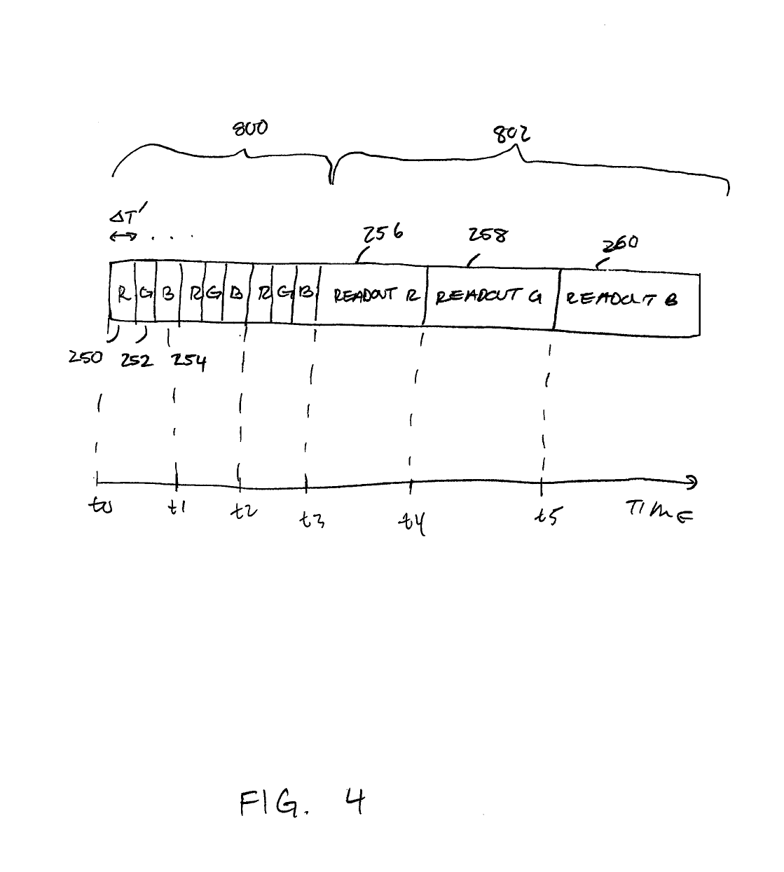

FIG. 4 shows a timing diagram for illustrating an exposure and readout sequence associated with a monochrome image sensor that captures color images with multi-storage-node image pixels in accordance with an embodiment of the present invention. As shown in FIG. 4, three artificial light sources may be used to sequentially illuminate a scene between times t0 and t1 without being interrupted by a readout operation. For example, red (R), green (G), and blue (B) artificial light sources may be used to illuminate the scene. During a red exposure phase 250, red light may be used to illuminate a scene to be captured. During red exposure phase 250, multi-storage-node image pixels 190 may be used to capture the red light reflected from the scene. Red exposure phase 250 may be immediately followed by a green exposure phase 252 in which green light is used to illuminate the scene. During green exposure phase 252, multi-storage-node image pixels 190 may be used to capture the green light reflected from the scene. Green exposure phase 252 may be immediately followed by a blue exposure phase 254 in which blue light is used to illuminate the scene. During blue exposure phase 254, multi-storage-node image pixels 190 may be used to capture the blue light reflected from the scene. Red exposure phase 250, green exposure phase 252, and blue exposure phase 254 may have duration ΔT′. Duration ΔT′ may be substantially shorter than exposure time ΔT of FIG. 3.

Phases 250, 252, and 254 may be repeated between times t1 and t2 and again between times t2 and t3. This period during which rapid interleaving exposure using multiple light sources is performed may be referred to as an interleaving exposure phase 800. During phase 800, multi-storage-node image pixels 190 may be used to store charge generated in each of the red-light-illuminated scene, green-light-illuminated scene, and the blue-light-illuminated scene in rapid succession. In order to ensure adequate exposure to each light color for multi-storage-node image pixels 190, the total amount of exposure time associated with each of phases 250, 252, and 254 may be equal to ΔT of FIG. 3 (e.g., 3ΔT′ may be equal to ΔT, assuming the color interleaving scheme is repeated three times as shown in FIG. 4).

Interleaved exposure phase 800 may then be followed by a pixel readout phase 802. Pixel readout phase 802 may include red readout phase 256 (from time t3 to t4), a green readout phase 258 (from time t4 to t5), and a blue readout phase 260 (from time t5 to t6). During red readout phase 256, charge generated as a response to illumination with red light may be read out from pixel 190 using readout circuitry 142 to obtain a red image. During green readout phase 258, charge generated as a response to illumination with green light may be read out from pixel 190 using circuitry 142 to obtain a green image. During blue readout phase 260, charge generated as a response to illumination with blue light may be read out from pixel 190 using circuitry 142 to obtain a blue image. The red image, green image, and blue image may then be combined to produce a color image with reduced color artifacts that are caused by motion.

The interleaving exposure and readout sequence as shown in FIG. 4 is merely illustrative. If desired, red exposure phase 250, green exposure phase 252, and blue exposure phase 254 may be performed in any desired order. Each exposure phase may correspond to any color of light (e.g., red, green, blue, ultra-violet, infrared, white, orange, etc.), and more or less than three artificial light sources (and their corresponding exposure and readout phases) may be used. Likewise, red readout phase 256, green readout phase 258, and blue readout phase 260 may occur in any suitable order.

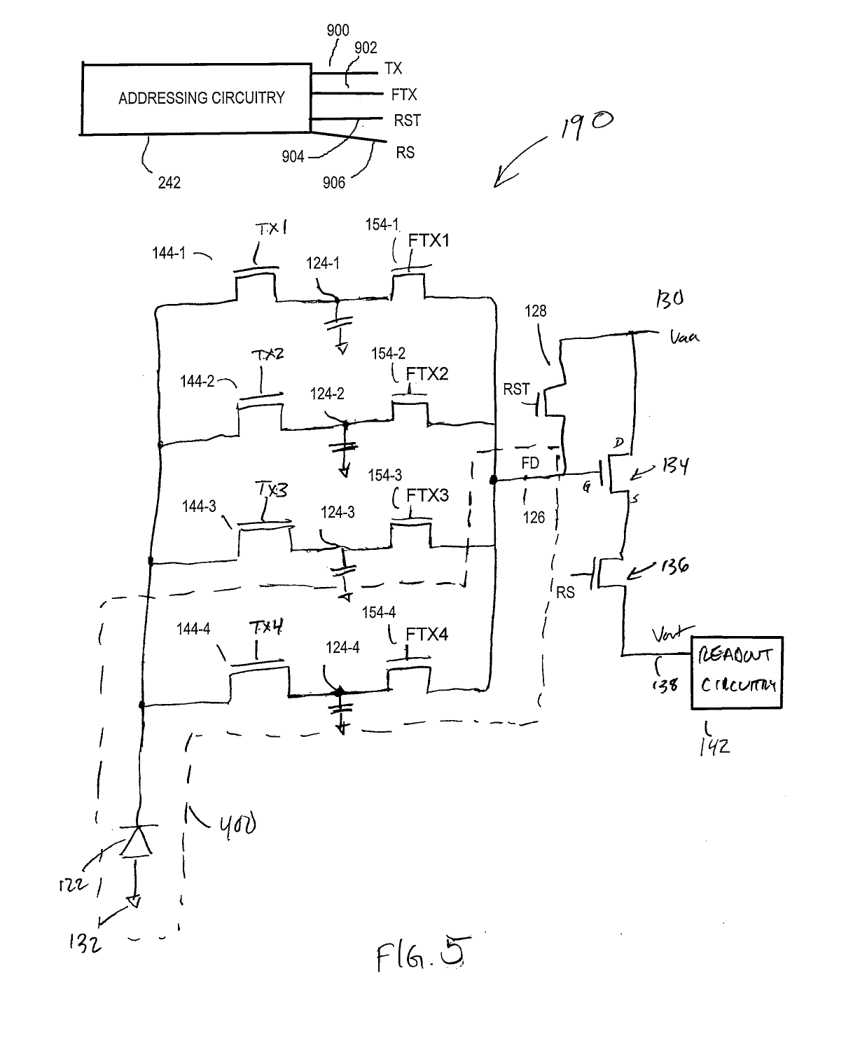

FIG. 5 is a circuit diagram of an illustrative multi-storage-node image pixel that can be formed on a monochrome image sensor in accordance with an embodiment of the present invention. As shown in FIG. 5, multi-storage-node image pixel 190 may include a photodiode 122 coupled between a ground terminal 132 and four storage node transfer gates 144 (e.g., storage region transfer gates 144-1, 144-2, 144-3, and 144-4). In the example of FIG. 5, a first storage node transfer gate 144-1 may be coupled between photodiode 122 and a first storage node 124-1; a second storage node transfer gate 144-2 may be coupled between photodiode 122 and a second storage node 124-2; a third storage node transfer gate 144-3 may be coupled between photodiode 122 and a third storage node 124-3; and a fourth storage node transfer gate 144-4 may be coupled between photodiode 122 and a fourth storage node 124-4. Storage node transfer gates may sometimes be referred to as storage region transfer gates. Storage nodes 124 (e.g., storage regions 124-1, 124-2, 124-3, and 124-4) may be implemented using photodiode-like structures, capacitors, or other suitable components that store charge.

Floating diffusion node transfer gates 154 may be coupled between storage nodes 124 and a floating diffusion node 126 (e.g., a first floating diffusion node transfer gate 154-1 may be coupled between first storage node 124-1 and floating diffusion node 126, a second floating diffusion node transfer gate 154-2 may be coupled between second storage node 124-2 and floating diffusion node 126, etc.). Floating diffusion node transfer gates may sometimes be referred to as floating diffusion region transfer gates. Stored charge may be selectively transferred to floating diffusion node 126 one at a time (e.g., floating diffusion node 126 may receive charge from only one of storage nodes 124 at any given point in time during charge readout operations). Charge may be temporarily stored at floating diffusion node 126 prior to being read out of pixel 190.

Floating diffusion node 126 may be coupled to reset transistor 128 and source follower transistor 134. The drain D of source follower transistor 134 and reset transistor 128 may be coupled to a positive power supply terminal 130 (e.g., a power supply terminal on which a positive power supply voltage Vaa or another reset-level voltage may be provided). A row select transistor 136 may be coupled to an output path 138 and source S of source follower 134. Output path 138 may be coupled to readout circuitry 142. Output signals Vout may be formed on output path 138 for sampling by readout circuitry 142.

Incoming light may be detected by a photosensitive element such as photodiode 122. Photodiode 122 may convert the light to electric charge. The monochrome image sensor on which pixel 190 is formed may also include addressing circuitry 242. Addressing circuit 242 may be used to provide control signals to storage node transfer gates 144 via path 900, to floating diffusion node transfer gates 154 via path 902, to reset transistor 128 via path 904, and to row select transistor 136 via path 906. In particular, addressing circuitry 242 may feed transfer signals TX to storage node transfer gates 144 via path 900 (e.g., a first transfer signal TX1 may be fed to first storage node transfer gate 144-1, a second transfer signal TX2 may be fed to second storage node transfer gate 144-2, etc.). During exposure of the multi-storage-node image pixels 190, transfer signals TX may be asserted for a particular storage node transfer gate 144, allowing an image signal created by photodiode 122 in response to incoming light to flow to the associated storage node 124.

Transfer signals TX (e.g., storage node transfer gate control signals TX1, TX2, TX3, and TX3) may be synchronized with the artificial light sources that illuminate a scene so that only one storage node transfer gate is active when illuminating a scene using a particular color of light, allowing each storage node 124 to store the image signal associated with each color of light. First transfer signal TX1 may turn on first storage node transfer gate 144-1 during red exposure phase 250 for a duration ΔT' (as shown in FIG. 4), allowing the image signal generated by photodiode 122 in response to the red light reflected from the scene to flow to first storage node 124-1. First transfer signal TX1 may be deasserted to prevent image signals from flowing to first storage node 124-1 while an asserted transfer signal TX2 is provided to second storage node transfer gate 144-2 during green exposure phase 252, allowing the image signal generated by photodiode 122 to flow to second storage node 124-2. Second transfer signal TX2 may then be deasserted as a third asserted transfer signal TX3 is provided to a third storage node transfer gate 144-3 during blue exposure phase 253, allowing the image signal generated by photodiode 122 in response to the blue light reflected from the scene to flow to a third storage node 124-3.

Addressing circuitry 242 may supply floating diffusion node transfer gate control signals FTX to floating diffusion node transfer gates 154 via path 902 (e.g., a first floating diffusion node transfer signal FTX1 may be supplied to a first floating diffusion node transfer gate 154-1, a second floating diffusion node transfer signal FTX2 may be supplied to a second floating diffusion node transfer gate 154-2, etc.). When the floating diffusion node transfer gate control signals are asserted, image signals stored in storage nodes 124 may be transferred to floating diffusion node 126. An asserted first floating diffusion node transfer signal FTX1 may be provided to first floating diffusion node transfer gate 154-1 during red readout phase 256 to allow the image signals stored in first storage node 124-1 during red exposure phase 250 to travel to floating diffusion node 126. The image signals on floating diffusion region 126 are conveyed to row select transistor 136 by source-follower transistor 134. During pixel readout phase 802, readout circuitry 142 may provide an asserted row select signal RS to row select transistor 136 to allow the image signals to be conveyed to readout circuitry 142 through output path 138. This process may be repeated during green readout phase 258 for the image signals stored on second storage node 124-2 and again during blue readout phase 260 for the image signals stored on third storage node 124-3.

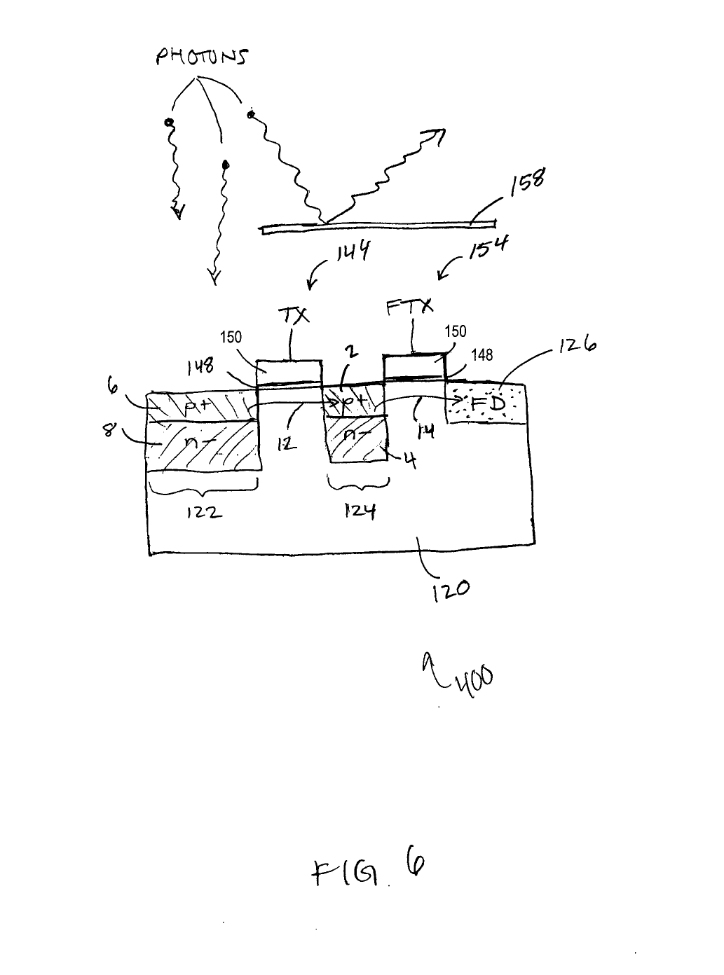

A cross-sectional side view of a portion of multi-storage-node image pixel 190 such as dashed portion 400 of FIG. 5 is shown in FIG. 6. Portion 400 may represent one signal pathway in multi-storage-node image pixel 190 for conveying image signals associated with one color of light during interleaving exposure phase 800. As shown in FIG. 6, photodiode 122 may be formed in a substrate 120. Photodiode 122 may include an n−doped layer 8 and a p+doped layer 6 that is formed over n−doped layer 8. Photodiode 122 may receive photons incident from a scene and convert the received photons into electric charge (e.g., into electrons).

Storage node transfer gate 144 may be formed on substrate 120 and adjacent to photodiode 122. Storage node transfer gate 144 may include a gate conductor 150 and a gate oxide layer 148 interposed between gate conductor 150 and the surface of substrate 120 on which gate 144 is formed. Storage node region (or storage region) 124 may be formed in substrate 120 adjacent to transfer gate 144, where photodiode 122 and storage region 124 are separated by a channel region in substrate 120 directly underneath transfer gate 144. Storage region 124 may include a second n- doped layer 4 that is be formed in substrate 120 and a second p+doped layer 2 that is formed over n−doped layer 4. Storage region 124 formed in a photodiode configuration in this way may be used to temporarily accumulate charge. A shielding layer such as shielding structure 158 may be formed over storage region 124 to prevent incoming photons from generating additional charge in storage region 124. Shielding structure 158 may be formed from a conductor, metal, or any other suitable material that blocks incoming light from reaching storage region 124.

Floating diffusion node transfer gate 154 may be formed on top of substrate 120 and adjacent to storage region 124 so that storage region 124 is interposed between storage node transfer gate 144 and floating diffusion node transfer gate 154. Floating diffusion node transfer gate 154 may include a gate conductor 150 and a gate oxide layer 148 interposed between gate conductor 150 of gate 154 and the surface of substrate 120 on which gate 154 is formed. A floating diffusion region 126 may be formed in substrate 120 adjacent to transfer gate 154 such that transfer gate 154 is interposed between storage region 124 and floating diffusion region 126. Floating diffusion region 126 may be implemented using a region of doped semiconductor (e.g., a doped silicon region formed in substrate 120 via ion implantation, impurity diffusion, or other doping techniques). Floating diffusion region 126 may exhibit a capacitance that can be used to store the charge that has been transferred from storage region 124.

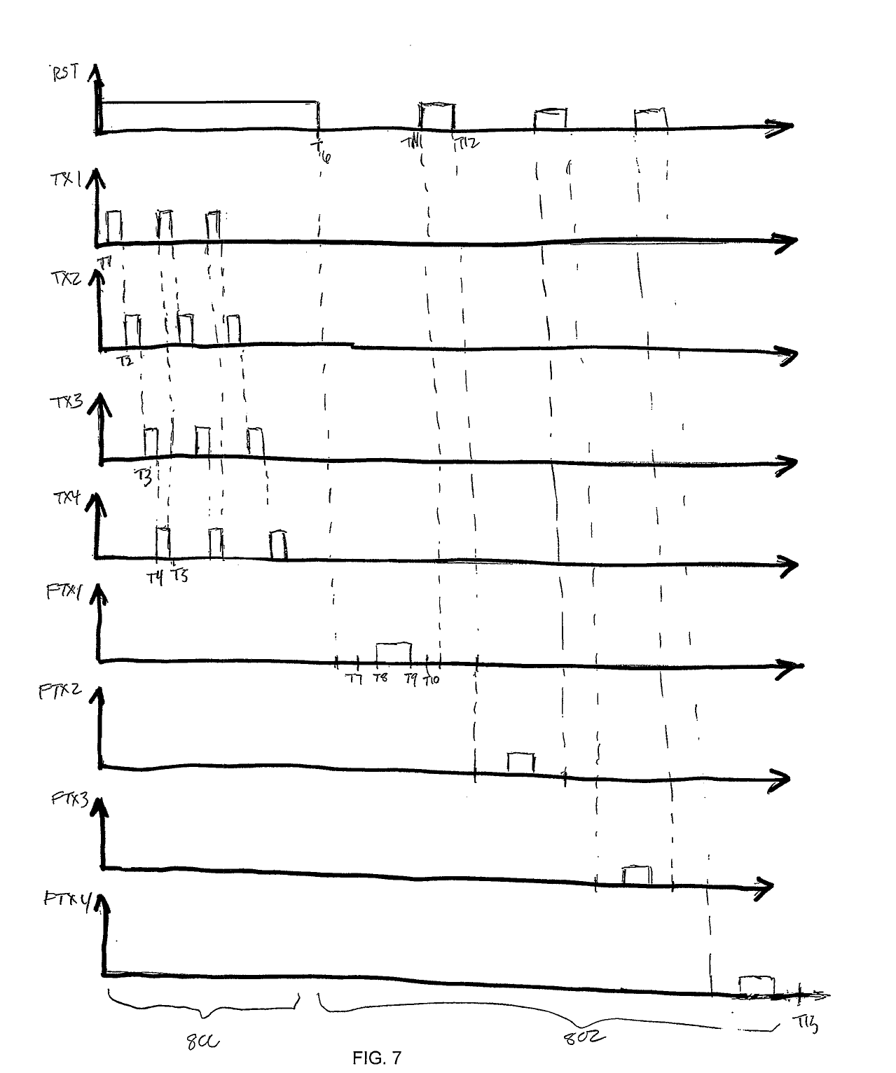

FIG. 7 is a timing diagram that illustrates the operation of multi-storage-node image pixel 190 as shown in FIGS. 5 and 6, in which artificial light of four colors is used to illuminate a scene. Addressing circuitry 242 may supply reset control signal RST, storage node transfer signals TX, row select control signals RS, and floating diffusion transfer signals FTX to multi-storage-node image pixel 190.

Addressing circuitry 242 may supply first storage node transfer signal TX1 to first storage node transfer gate 144-1 via path 900, as shown in FIG. 5. At time T1, first storage node transfer signal TX1 may be asserted to turn on first storage node transfer gate 144-1 while all of the other storage node transfer gates 144 are turned off, allowing charge generated by photodiode 122 to flow to first storage node 124-1 over a path 12, as shown in FIG. 6. Storage node transfer gates 144 may be configured so that charge can only flow in one direction (i.e. the direction indicated by path 12) while storage node transfer signals TX are asserted. First storage node transfer signal TX1 may be synchronized with a light of a first color (e.g., red, green, blue, infrared, ultraviolet, white, etc.) that is used to illuminate a scene to be imaged, so that when first storage node transfer signal TX1 is asserted, light of the first color reflects off of the scene and is captured by the photodiode.

The charge generated by photodiode 122 in response only to light of the first color may thereby flow to first storage node 124-1.

Second storage node transfer signal TX2 may be supplied to second storage node transfer gate 144-2. At time T2, second storage node transfer signal TX2 may be asserted to turn on second storage node transfer gate 144-2, and first signal TX1 may be deasserted to turn off first storage node transfer gate 144-1. Second storage node transfer signal TX2 may be synchronized with a light of a second color that is used to illuminate the scene, so that when second storage node transfer signal TX2 is asserted, the second color light reflects off of the scene and is captured by photodiode 122. At the same time, all of the other color lights may be turned off. The charge generated by photodiode 122 in response to only light of the second color may thereby flow to second storage node 124-2.

Third storage node transfer signal TX3 may be supplied to third storage node transfer gate 144-3. At time T3, third storage node transfer signal TX3 may be asserted to turn on third storage node transfer gate 144-3, and second signal TX2 may be deasserted to turn off second storage node transfer gate 144-2. Third storage node transfer signal TX3 may be synchronized with a light of a third color that is shown on the scene, so that when third storage node transfer signal TX3 is asserted, the third color light reflects off of the scene and is captured by photodiode 122. At the same time, all of the other color lights may be turned off. The charge generated by photodiode 122 in response to only light of the third color may thereby flow to third storage node 124-3.

A fourth storage node transfer signal TX4 may be supplied to a fourth storage node transfer gate 144-4. At time T4, fourth storage node transfer signal TX4 may be asserted to turn on a fourth storage node transfer gate 144-4, and third signal TX3 may be deasserted to turn off third storage node transfer gate 144-3. Fourth storage node transfer signal TX4 may be synchronized with a light of a fourth color that is shown on the scene, so that when fourth storage node transfer signal TX4 is asserted, the fourth color light reflects off of the scene and is captured by photodiode 122. At the same time, all of the other color lights may be turned off. The charge by photodiode 122 in response to only light of the fourth color may thereby flow to a fourth storage node 124-4.

At time T5, fourth storage node transfer signal TX4 may be deasserted to turn off fourth storage node transfer gate 144-4. At the same time, the fourth color light may be turned off. Storage node transfer gates 144 and floating diffusion node transfer gates 154 may be formed to allow charge to only flow in one direction (i.e., from photodiode 122 to storage nodes 124 and from storage nodes 124 to floating diffusion node 126, respectively) when the transfer signals TX are asserted. The control signals between times T1 and T5 may then be repeated a number of times during interleaving exposure phase 800 to allow the charge generated by photodiode 122 corresponding to each of the four colors of light to be accumulated in the separate storage nodes 124 so that an adequate exposure level is achieved for each light color. In this way, the charge corresponding to light of each color can be stored separately and in rapid succession prior to readout from multi-storage-node image pixel 190.

Reset control signal RST may be supplied to reset transistor 128 of multi-storage-node image pixel 190. Between times T1 and T6, reset control signal RST may be asserted to turn on reset transistor 128 to reset floating diffusion node 126. At time T6, reset control signal RST may be deasserted. At time T7, addressing circuitry 242 may assert row select control signal RS to turn on row select transistor 136, enabling the signal associated with the charge stored in floating diffusion node 126 to flow to output path 138 to be sampled by readout circuitry 142. This reset-level signal may be used as a reference signal to account for any bias in the image signal.

First floating diffusion node transfer signal FTX1 may be supplied to first floating diffusion node transfer gate 154-1. At time T8, first floating diffusion node transfer signal FTX1 may be asserted to turn on first floating diffusion node transfer gate 154-1 while all of the other floating diffusion node transfer gates 154 are turned off. This allows the charge that is associated with the first color light and that is stored in first storage node 124-1 during interleaving exposure phase 800 to flow to floating diffusion region 126 via a path 14 (see, FIG. 6). Floating diffusion node transfer gates 154 may be configured so that charge may only flow in one direction (i.e., the direction indicated by arrow 14) while floating diffusion node transfer signals FTX are asserted. At time T9, first transfer signal FTX1 may be deasserted to turn off floating diffusion node transfer gate 154-1. At time T10, addressing circuitry 242 may assert control signal RS to turn on row select transistor 136 to allow the charge that was transferred from first storage node 124-1 to flow from floating diffusion node 126 to readout circuitry 142 over output path 138. At time T11, reset signal RST may be asserted to turn on reset transistor 128, allowing the reset-level voltage to be provided on floating diffusion node 126. At time T12, reset control signal RST may be deasserted.

This process may be sequentially repeated between times T12 and T13 for the remaining floating diffusion transfer signals FTX2, FTX3, and FTX4, allowing for different amounts of charge generated in response to the second, third, and fourth light sources to flow from storage nodes 124-2, 124-3, and 124-4, respectively, to floating diffusion region 126 via paths 14 (FIG. 6). An image signal associated with each charge may be sampled by readout circuitry 142 via output path 138. The image signal corresponding to each light color may be transferred to floating diffusion node 126 and sampled by readout circuitry 142 before the next image signal corresponding to a different light color is transferred and sampled. In this way, the image signal corresponding to each light color can be sequentially and separately sampled by readout circuitry 142 during pixel readout phase 802, and all readout operations may occur after interleaving exposure phase 800. This may allow for the elimination of color artifacts because the readout time between back-to-back exposures with different color lights is eliminated.

Multi-storage-node image pixel 190 of FIGS. 5-7 is merely illustrative. If desired, multi-storage-node image pixel 190 may be configured to support imaging with any desired number of light sources. One storage node transfer gate 144, one storage node 124, and one floating diffusion node transfer gate 154 may be implemented for each artificial light source that is used. Interleaving exposure phase 800 may include asserting each of the number of storage node transfer signals TX sequentially, and subsequently reasserting the storage node transfer signals to suitably accumulate charge throughout the exposure. Storage node transfer signals TX may be asserted in any order and for any suitable duration, as long as the assertion of one storage node transfer signal TX does not overlap with the assertion of any other transfer signal TX, and as long as all transfer signals TX are deasserted by time T6 (e.g., as long as all the transfer gate control signals are deasserted prior to readout operations). Storage node transfer signals TX may also be asserted any number of times. Pixel readout phase 802 may include reset-level sampling, image signal transfer from storage nodes 124 to floating diffusion node 126, and image sampling by readout circuitry 142 for each set of transfer gates 144 and 154 that are implemented.

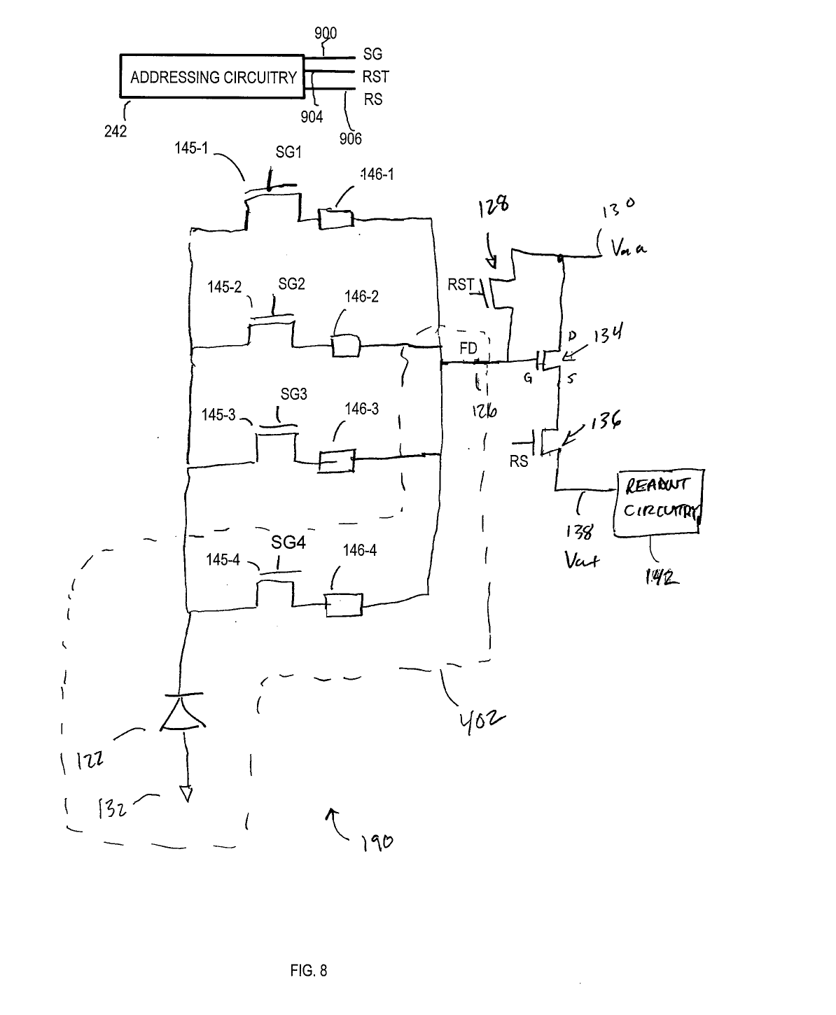

An alternate configuration of multi-storage-node image pixel 190 that includes a storage gate with a built-in voltage barrier is shown in FIG. 8 in accordance with an embodiment of the present invention. As shown in FIG. 8, a multi-storage-node image pixel 190 may include photodiode 122 coupled between a ground terminal 132 and four storage gates 145 (e.g., storage gates 145-1, 145-2, 145-3, and 145-4). Storage gates 145 may be coupled between photodiode 122 and voltage barriers 146 (e.g., a first storage gate 145-1 may be coupled between photodiode 122 and a first voltage barrier 146-1, a second storage gate 145-2 may be coupled between photodiode 122 and a second voltage barrier 146-2, etc.). Voltage barriers 146 may sometimes be referred to as charge barrier structures or charge barrier regions. Each storage gate 145 may be formed over a first controllable region that serves as a channel region through which charge can be conveyed and a second controllable region that serves as a charge storage region.

Voltage barriers 146 may be coupled between storage gates 145 and floating diffusion node 126 (e.g., a first voltage barrier 146-1 may be coupled between first storage gate 145-1 and floating diffusion node 126, a second voltage barrier 146-2 may be coupled between second storage gate 145-2 and floating diffusion node 126, etc.). Voltage barriers 146 may serve to prevent charge from flowing from the charge storage region associated with storage gates 145 to floating diffusion node 126 during exposure operations.

Floating diffusion node 126 may be coupled to reset transistor 128 and source follower transistor 134. The drain D of source follower transistor 134 and reset transistor 128 may be coupled to a positive power supply terminal 130. A positive power supply voltage (e.g., voltage Vaa or another reset-level voltage) may be supplied at terminal 130. A row select transistor 136 may be coupled to an output path 138 and the source S of source follower 134. Output signals Vout may be provided on output path 138 for sampling with readout circuitry 142.

Incoming light may be detected by a photosensitive element such as photodiode 122. Photodiode 122 may convert the light to electric charge. The monochrome image sensor on which pixel 190 is formed may also include addressing circuitry 242. Addressing circuitry 242 may be coupled to storage gates 145 via path 900, to reset transistor 128 via path 904, and to row select transistor 136 via path 906. Addressing circuitry 242 may supply gate control signals SG to storage gates 145 (e.g., a first storage gate signal SG1 may be supplied to first storage gate 145-1, a second storage gate signal SG2 may be supplied to second storage gate 145-2, etc.). Gate signals SG may be driven to a first voltage, a second voltage that is less than the first voltage, and a third voltage that is less than the first and second voltages (herein referred to as high (V_{H}), middle (V_{M}), and low (V_{L}) voltages, respectively).

When storage gate control signal SG is driven to V_{H}, charge generated by photodiode 122 may flow to storage gates 145. When storage gate control signal SG is driven to V_{M}, this charge may be temporarily stored in storage gates 145 (e.g., charge may neither flow back to photodiode 122 nor flow pass voltage barriers 146 to floating diffusion node 126). When storage gate control signal SG is driven to V_{L}, charge that is stored in storage gates 145 may be allowed to flow past voltage barriers 146 to floating diffusion node 126. Voltage barriers 146 may be formed with a low electrostatic potential that serves to prevent charge from flowing from storage gates 145 to floating diffusion node 126 when gate signal SG is driven to V_{M} or V_{H}. When gate signal SG is driven to V_{L}, charge stored in storage gates 145 may overcome the low electrostatic potential in voltage barrier 146, allowing the charge to flow from storage gates 145 to floating diffusion node 126.

During exposure of the multi-storage-node image pixels 190, gate signals SG may be supplied to a particular storage gate 145 and driven to V_{H} allowing charge generated by photodiode 122 in response to incoming light to flow to the associated storage node 145. Gate signals SG may be driven to V_{M} to store the charge in storage node 145 while the gate signals SG applied to other storage gates 145 are driven to V_{H}. Gate signals SG may each be synchronized with a different color artificial light source that is used to illuminate a scene, so that only one storage gate is supplied with a gate signal SG that is driven to V_{H} while each color of light illuminates the scene. In this way, each storage gate 145 may separately store the charge generated by photodiode 122 in response to light of each color. Gate signals SG may be driven to V_{L} to transfer the charge stored in storage gates 145 to floating diffusion node 126 through corresponding voltage barriers 146. Image signals associated with the charge transferred to floating diffusion node 126 may be provided on output path 138 for sampling by readout circuitry 142.

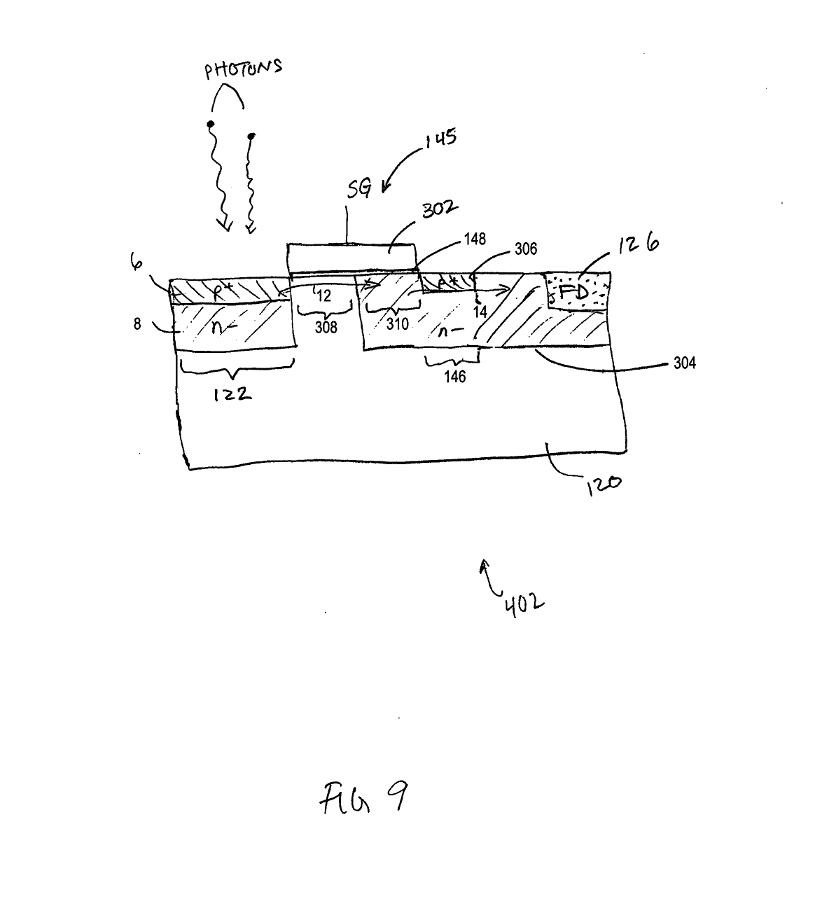

A cross-sectional side view of a portion of pixel 190 such as dashed portion 402 is shown in FIG. 9. Portion 402 may represent one signal path for conveying charge associated with one color of light during interleaving exposure phase 800. As shown in FIG. 9, photodiode 122 may be formed in a substrate 120. Photodiode 122 may include a first n−doped layer 8 and a first p+doped layer 6 that is formed over n- doped layer 8. Photodiode 122 may receive photons incident from a scene and convert them into electric charge.

A storage gate 145 may be formed on top of substrate 120 and adjacent to photodiode 122. Storage gate 145 may include storage gate conductor 302 and gate oxide layer 148 interposed between gate conductor 302 and the surface of substrate 120 on which gate 145 is formed. A second n−doped region 304 may be formed in substrate 120 so that a portion of region 304 is formed under storage gate 145. The portion of region 304 that is formed under storage gate 145 may serve as a storage gate well region 310 that temporarily stores charge while storage gate control signal is driven to V_{M} (e.g., storage region 310 may be formed directly beneath storage gate 145). Storage gate well region 310 may be physically separated from photodiode 122 by a portion of substrate 120 that serves as a storage gate channel region 308 for storage gate 145. Storage gate channel region 308 may allow charge to flow from photodiode 122 to charge well region 310 along path 12 when signal SG is driven to V_{H}.

Floating diffusion region 126 may also be formed in region 304. Floating diffusion region 126 may be formed from a region of doped semiconductor (e.g., a doped silicon region formed in a substrate by ion implantation, impurity diffusion, or other doping techniques). Floating diffusion region 126 may exhibit a capacitance that can be used to store the charge that has been transferred from storage gates 145. Voltage barrier region 146 may be formed in region 304 and may be interposed between storage gate well region 310 and floating diffusion region 126. Voltage barrier region 146 may include second P+doped layer 306. Voltage barrier region 146 may act as a potential barrier that selectively prevents charge from flowing between storage gate well region 310 and floating diffusion region 126.

When storage gate signal SG is driven to V_{H}, charge may flow from photodiode 122 through storage gate channel region 308 (e.g., over path 12) to be stored in storage gate well region 310. When gate signal SG is driven to V_{M}, no charge may be allowed to flow between storage gate well region 310 and photodiode 122 via channel region 308. Voltage barrier region 146 may form a potential barrier that serves to prevent charge from flowing between storage gate well region 310 and floating diffusion region 126 when gate signal SG is driven to V_{H} or V_{M}. In this way, storage gate well region 310 may serve as a temporary storage region for the charge generated by photodiode 122 while gate signal SG is driven to V_{H} or V_{M}. When gate signal SG is driven to V_{L}, storage gate well region 310 may allow the charge stored in storage gate well region 310 to flow over voltage barrier region 146 to floating diffusion region 126, as indicated by path 14. Separate storage gate channel regions 308 and storage gate well regions 310 may be implemented for each storage gate 145 in multi-storage-node image pixel 190, as shown in FIG. 8 (e.g., first storage gate 145-1 may include first storage gate channel region 308-1 and first storage gate well region 310-1, second storage gate 145-2 may include second storage gate channel region 308-2 and second storage gate well region 310-2, etc.).

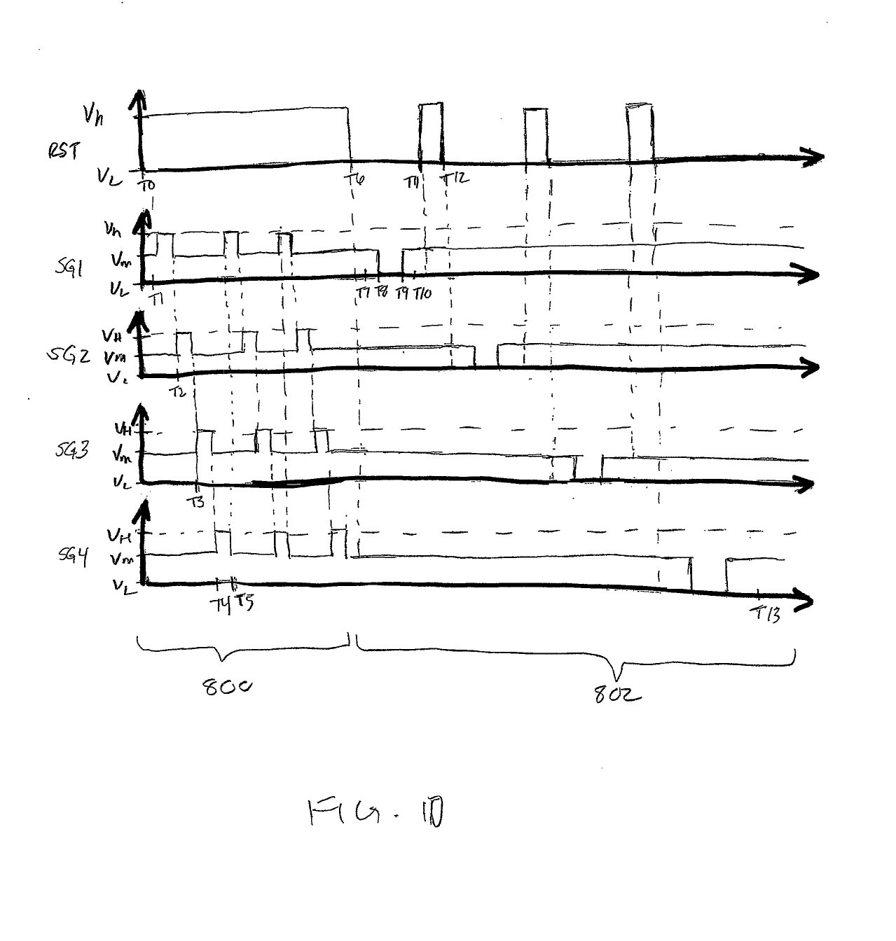

FIG. 10 is a timing diagram that illustrates the operation of multi-storage-node image pixel 190 of the type described in FIGS. 8 and 9, in which four colors of artificial light are used to illuminate a scene. As shown in FIG. 8, addressing circuitry 242 may supply first gate signal SG1 to first storage gate 145-1. At time T0, all four storage gate signals SG (e.g., SG1, SG2, SG3, and SG4) may be driven to V_{M}, preventing charge from flowing across storage gate channel regions 308 to storage gate well regions 310, as shown in FIG. 9. At time T1, first gate signal SG1 may be driven to V_{H} to allow charge generated by photodiode 122 to flow through first storage gate channel region 308-1 to first storage gate well region 310-1, as indicated by path 12. First gate signal SG1 may be synchronized with a light of a first color (e.g., red, green, blue, infrared, ultraviolet, white, etc.) that is used to illuminate a scene to be imaged, so that only light of the first color reflects off of the scene and is captured by the photodiode when first gate signal SG1 is driven to V_{H}. The charge generated by photodiode 122 in response only to light of the first color may thereby flow to first storage gate well region 310-1.

At time T2, first gate signal SG1 may be driven to V_{M} to block charge from flowing through first storage gate channel region 308-1, and the first color light may be turned off. At the same time, second gate signal SG2 may be driven to V_{H} to allow charge generated by photodiode 122 to flow through second storage gate channel region 308-2 to second storage gate well region 310-2, as indicated by path 12. Second gate signal SG2 may be synchronized with a light of a second color that is used to illuminate the scene to be imaged, so that only light of the second color reflects off the scene and is captured by photodiode 122 when second gate signal SG2 is driven to V_{H}. The charge generated by photodiode 122 in response only to light of the second color may thereby flow to second storage gate well region 310-2.

At time T3, second gate signal SG2 may be driven to V_{M} to block charge from flowing through second storage gate channel region 308-2, and the second color light may be turned off. At the same time, third gate signal SG3 may be driven to V_{H} to allow charge generated by photodiode 122 to flow across third storage gate channel region 308-3 to third storage gate well region 310-3 over path 12. Third gate signal SG3 may be synchronized with a light of a third color that is used to illuminate the scene to be imaged, so that only light of the third color reflects off the scene and is captured by photodiode 122 when third gate signal SG3 is driven to V_{H}. The charge generated by photodiode 122 in response only to light of the third color may thereby flow to third storage gate well region 310-3.

At time T4, third gate signal SG3 may be driven to V_{M} to block charge from flowing through third storage gate channel region 308-3, and the third color light may be turned off. At the same time, fourth gate signal SG4 may be driven to V_{H} to allow charge generated by photodiode 122 to flow across fourth storage gate channel region 308-4 to fourth storage gate well region 310-4 over path 12. Fourth gate signal SG4 may be synchronized with a light of a fourth color that is used to illuminate the scene to be imaged, so that only light of the fourth color reflects off the scene and is captured by photodiode 122 when fourth gate signal SG4 is driven to V_{H}. The charge generated by photodiode 122 in response only to light of the fourth color may thereby flow to fourth storage gate well region 310-4.

At time T5, fourth gate signal SG4 may be driven to V_{M} to block charge from flowing through fourth storage gate channel region 308-4 and to turn off the fourth color light. The control signals driven to V_{H} and V_{M} between times TO and T5 may be repeated a number of times during interleaving exposure phase 800 to allow the charge generated by photodiode 122 corresponding to each of the four colors of light to be accumulated in separate storage gate well regions 146, so that an adequate exposure level is achieved for each light color. In this way, the charge generated by photodiode 122 associated with light of each color may be stored separately and in rapid succession prior to readout from multi-storage-node image pixel 190.

Addressing circuitry 242 may supply reset control signal RST to reset transistor 128 of multi-storage-node image pixel 190 (see FIG. 8). Between times T1 and T6, reset control signal RST may be asserted to turn on reset transistor 128, allowing a reset-level voltage that is supplied to power supply terminal 130 to be provided on floating diffusion node 126. At time T6, reset control signal RST may be deasserted. At time T7, row select control signal RS may be asserted to turn on row select transistor 136, enabling the charge stored in floating diffusion node 126 to flow to output path 138 to be sampled by readout circuitry 142. This reset-level signal may be used as a reference signal to account for any bias in the image signal.

At time T8, first gate signal SG1 may be driven to V_{L} while all other gate signals SG are driven to V_{M}, allowing the charge associated with the first color light that is stored in first storage gate well region 310-1 to flow from first storage gate well region 310-1, through first voltage barrier region 146-1, to floating diffusion region 126, as indicated by path 14. At time T9, first gate signal SG1 may driven to V_{M}. At time T10, row select control signal RS may be asserted to turn on row select transistor 136 to allow the charge that was transferred from first storage gate well region 310-1 to flow to readout circuitry 142 via output path 138. At time T11, reset signal RST may be reasserted to turn on reset transistor 128, allowing the reset-level voltage to be provided on floating diffusion region 126. At time T12, reset control signal RST may be deasserted.

This process may be sequentially repeated between times T12 and T13 for the remaining gate signals SG2, SG3, and SG4, allowing for the separate amounts of charge associated with the second, third, and fourth color light sources to flow from storage gate well regions 310-2, 310-3, and 310-4, respectively, to floating diffusion region 126 via paths 14. An image signal associated with each charge may be sampled by readout circuitry 142 over output path 138. The image signal associated with each color light may be transferred to floating diffusion region 126 and sampled by readout circuitry 142 before the next charge corresponding to a different light color is transferred and sampled. In this way, the image signal corresponding to each light color can be sequentially and separately sampled by readout circuitry 142 during pixel readout phase 802, and all readout operations may occur after multi-storage-node image pixel 190 is exposed to light from the scene. This may allow for the elimination of color artifacts because the readout time between back-to-back exposures with different color lights is eliminated.

Multi-storage-node image pixel 190 of FIGS. 8-10 is merely illustrative. If desired, multi-storage-node image pixel 190 may be configured to support imaging with any desired number of light sources. One storage gate 145 and one voltage barrier 146 may be implemented for each artificial light source that is used. Interleaving exposure phase 800 may include sequentially toggling the storage gate signals SG to build adequate charge throughout the exposure phase. Gate signals SG may be driven to V_{H} in any order and for any suitable duration, as long as driving one gate signal SG to V_{H} does not overlap with driving any other gate signal SG to V_{H}, and as long as all of the gate signals SG are driven to V_{M} by time T6. Gate signals SG may also be driven to V_{H} any number of times. Pixel readout phase 802 may include reset-level sampling, charge transfer from storage gate well regions 310 to floating diffusion 126, and image signal sampling by readout circuitry 142 for each storage gate 145 that is implemented.

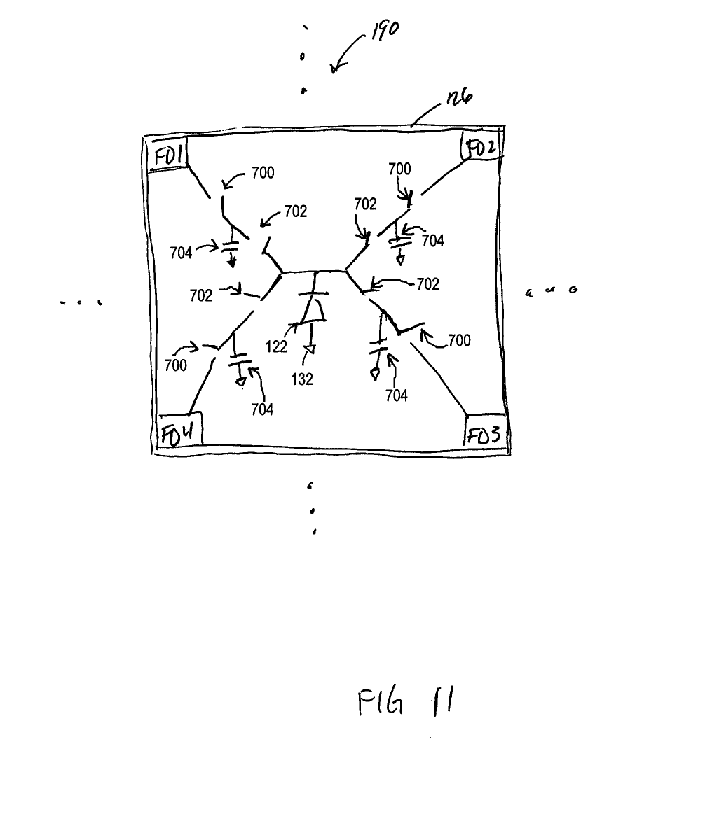

Multi-storage-node image pixel 190 of both embodiments shown in FIGS. 5-7 and FIGS. 8-10 may be arranged in the symmetric arrangement of FIG. 11 in accordance with an embodiment of the present invention. Each photodiode 122 in multi-storage-node image pixel 190 may be coupled radially to four first gates 702. First gates 702 may include the four storage node transfer gates 144 of FIG. 5 or the four storage gates 145 of FIG. 8. Storage elements 704 may be interposed between first gates 702 and second gates 700. Storage elements 704 may include the four storage nodes 124 of FIG. 5 or the four storage gate well regions 310 of FIG. 9. Second gates 700 may include the four floating diffusion node transfer gates 154 of FIG. 5 or the four voltage barrier regions 146 of FIG. 8. Second gates 700 may be coupled to one of four floating diffusion regions FD1-FD4. FD1-FD4 may be shorted to form one unified floating diffusion region 126 shared by each second gate 700. The symmetric arrangement of FIG. 11 may allow for cost-effective manufacture, space minimization, and for many multi-storage-node image pixels 190 to be easily arranged in an image pixel array.

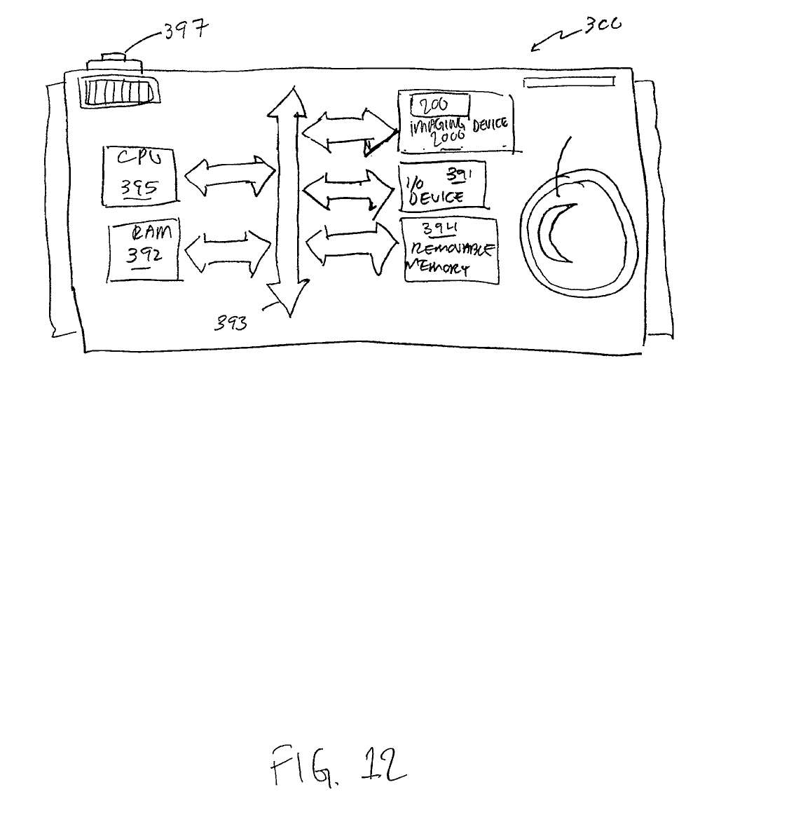

FIG. 12 shows in simplified form a typical processor system 300, such as a digital camera, which includes an imaging device 2000 (e.g., an imaging device 2000 such as the monochrome image sensor with multi-storage-node image pixels 190 of FIGS. 4-11 as described above). The processor system 300 is exemplary of a system having digital circuits that could include imaging device 2000. Without being limiting, such a system could include a computer system, still or video camera system, scanner, machine vision, vehicle navigation, video phone, surveillance system, auto focus system, star tracker system, motion detection system, image stabilization system, medical endoscope, and other systems employing an imaging device.

Many multi-storage-node image pixels 190 may be arranged in a pixel array 200. The processor system 300, for example a digital still or video camera system, generally includes a lens 396 for focusing an image on pixel array 200 when a shutter release button 397 is pressed, central processing unit (CPU) 395, such as a microprocessor which controls camera and one or more image flow functions, which communicates with one or more input/output (I/O) devices 391 over a bus 393. Imaging device 2000 also communicates with the CPU 395 over bus 393. The system 300 also includes random access memory (RAM) 392 and can include removable memory 394, such as flash memory, which also communicates with CPU 395 over the bus 393. Imaging device 2000 may be combined with the CPU, with or without memory storage on a single integrated circuit or on a different chip. Although bus 393 is illustrated as a single bus, it may be one or more busses or bridges or other communication paths used to interconnect the system components.

Various embodiments have been described illustrating a monochrome image sensor with multi-storage-node image sensor pixels. The multi-storage-node image pixels may be synchronized with artificial light sources of different colors to allow for rapid interleaving exposure of the monochrome image sensor to the artificial light sources prior to reading out the pixel, thereby reducing color artifacts from motion.

For example, the multi-storage-node image pixels may be exposed to one color of light during a first time period and a second color of light during a second time period that immediately follows the first time period. Charge generated by the multi-storage-node image sensor pixels in response to the first color light may be read out in a third time period sometime after the second time period, and charge generated in response to the second color light may be read out in a fourth time period following the third time period.

The multi-storage-node image pixels may each include a photosensitive element (e.g., a photodiode) and a number of storage regions that are selectively coupled to the photosensitive element. Each storage region may be used to store charge generated by the photosensitive element in response to exposing the photosensitive element to one of the artificial light colors. The multi-storage-node image pixel may include storage gates coupled between the photosensitive element and the storage regions. The storage gates may be formed over a portion of the storage regions. Each storage region may be used to store charge generated in response to exposing the photosensitive element to a respective color of light.

The storage gates may receive control signals that determine the flow of charge. In particular, the control signals may determine whether charge is allowed to flow from the photosensitive element to a selected one of the storage regions and may determine whether charge is allowed to flow from the selected storage region to the floating diffusion node for readout. A voltage barrier may be formed adjacent to each storage gate. This voltage barrier may be interposed between the floating diffusion region and the storage region associated with the adjacent storage gate. Voltage barriers formed using this configuration may serve to selectively prevent charge from flowing between the storage region and the floating diffusion region.

In another suitable arrangement, a multi-storage-node image pixel may include two sets of transfer gates coupled between a photosensitive element and a floating diffusion region. In particular, the first set of transfer gates may be coupled between the photosensitive element and multiple storage regions, whereas the second set of transfer gates may be coupled between the multiple storage regions and the floating diffusion region. The first set of transfer gates may be used to selectively transfer charge generated by the photosensitive element to a selected one of the storage regions. The second set of transfer gates may be used to selectively transfer charge stored in the storage regions to the floating diffusion region. Each storage region may be used to store charge generated in response to exposing the photosensitive element to a respective color of light.

The photosensitive element, floating diffusion region, and storage regions may be formed in a semiconductor substrate. The storage gates and transfer gates may be formed on the substrate. In particular, the photosensitive elements, floating diffusion regions, storage regions, and voltage barrier regions may be fabricated by doping the substrate with appropriate dopants (e.g., n-type dopants and/or p-type dopants).

The multi-storage node image pixels may be implemented in a system that also includes a central processing unit, memory, input-output circuitry, and an imaging device that further includes a pixel array, a lens for focusing light onto the pixel array, and a data converting circuit.

The foregoing is merely illustrative of the principles of this invention which can be practiced in other embodiments.

What is claimed is:

1. An image sensor pixel, comprising:
a photosensitive element;
a floating diffusion region; and
a plurality of charge storage regions coupled between the photosensitive element and the floating diffusion region.

2. The image sensor pixel defined in claim 1, further comprising:
a plurality of storage region transfer gates coupled between the photosensitive element and the plurality of charge storage regions.

3. The image sensor pixel defined in claim 2, further comprising:
a plurality of floating diffusion region transfer gates coupled between the floating diffusion region and the plurality of charge storage regions.

4. The image sensor pixel defined in claim 1, further comprising:
a plurality of floating diffusion region transfer gates coupled between the floating diffusion region and the plurality of charge storage regions.

5. The image sensor pixel defined in claim 1, wherein the plurality of charge storage regions comprises a plurality of photodiode-like structures.

6. The image sensor pixel defined in claim 5, further comprising:
a shielding layer formed above the plurality of charge storage regions, wherein the shielding layer blocks incoming light from reaching the plurality of charge storage regions.

7. The image sensor pixel defined in claim 1, further comprising:
a plurality of charge storage gates coupled between the floating diffusion region and the photosensitive element, wherein each charge storage region in the plurality of charge storage regions is formed directly beneath a respective one of the plurality of charge storage gates.

8. The image sensor pixel defined in claim 7, further comprising:
a plurality of charge barrier regions that selectively blocks charge from flowing between the plurality of charge storage regions and the floating diffusion region.

9. The image sensor pixel defined in claim 1, further comprising:
a substrate, wherein the photosensitive element is formed in the substrate;
a plurality of doped regions formed in the substrate; and
a plurality of storage gates formed on the substrate, wherein each storage gate in the plurality of storage gates is formed over a portion of a respective one of the plurality of doped regions, and wherein the portion of each doped region forms a respective one of the charge storage regions.

10. The image sensor pixel defined in claim 9, further comprising:
a plurality of voltage barrier regions formed in the plurality of doped regions, wherein each voltage barrier region in the plurality of voltage barrier regions is formed adjacent to a respective one of the charge storage regions, wherein the doped regions comprise regions of a first doping type, and wherein the voltage barrier regions comprises regions of a second doping type that is different from the first doping type.

11. A method for operating an image sensor pixel, comprising:
exposing the image sensor pixel to light of a first color during a first time period; and
exposing the image sensor pixel to light of a second color that is different than the first color during a second time period immediately following the first time period.

12. The method defined in claim 11, further comprising:
during the first time period, generating a first amount of charge with a photosensitive element and temporarily storing the first amount of charge in a first storage region in the image sensor pixel; and
during the second time period, generating a second amount of charge with the photosensitive element and temporarily storing the second amount of charge in a second storage region in the image sensor pixel that is different from the first storage region.

13. The method defined in claim 12, further comprising:
reading out the first amount of charge from the image sensor pixel during a third time period after the second time period.

14. The method defined in claim 13, further comprising:
reading out the second amount of charge from the image sensor pixel during a fourth time period immediately following the third time period.

15. The method defined in claim 12, further comprising:
during the first time period, transferring the first amount of charge from the photosensitive element to the first storage region via a storage region transfer gate that is coupled between the photosensitive element and the first storage region.

16. The method defined in claim 12, further comprising:
during the second time period, transferring the second amount of charge from the photosensitive element to the second storage region via a storage region transfer gate that is coupled between the photosensitive element and the second storage region.

17. The method defined in claim 11, further comprising:
exposing the image sensor pixel to light of a third color that is different than the first and second colors during a third time period immediately following the second time period, wherein exposing the image sensor pixel to light of the first, second, and third colors comprises performing an interleaving exposure operation; and
after performing the interleaving exposure operation, performing signal readout for charge that is generated during the first time period.

18. A system, comprising:
a central processing unit;
memory;
input-output circuitry; and
an imaging device, wherein the imaging device comprises:
a pixel array;
a lens that focuses an image on the pixel array; and
an image sensor pixel, wherein the image sensor pixel comprises:
a photosensitive element;
a floating diffusion region; and
a plurality of charge storage regions coupled between the photosensitive element and the floating diffusion region.

19. The system defined in claim 18, wherein the image sensor pixel further comprises:
a plurality of storage region transfer gates coupled between the photosensitive element and the plurality of charge storage regions.

20. The system defined in claim 18, wherein the image sensor pixel further comprises:
a plurality of floating diffusion region transfer gates coupled between the floating diffusion region and the plurality of charge storage regions.

21. The system defined in claim 18, wherein the image sensor pixel further comprises:
a plurality of charge storage gates coupled between the floating diffusion region and the photosensitive element, wherein each charge storage region in the plurality of charge storage regions is formed under a respective one of the plurality of charge storage gates.

22. The system defined in claim 21, wherein the image sensor pixel further comprises:
a plurality of charge barrier regions that selectively blocks charge from flowing between the plurality of charge storage regions and the floating diffusion region.
